(19) United States
(12) Patent Application Publication
(10) Pub. No.: US 2020/0028219 A1
(43) Pub. Date: Jan. 23, 2020

(54) FAULT-TOLERANT ELECTRONIC BATTERY SENSING

(71) Applicant: NAVITAS SOLUTIONS, INC., Hillsborough, NJ (US)

(72) Inventors: Jaesik Lee, Basking Ridge, NJ (US); Inseop Lee, Pittstown, NJ (US); Minkyu Lee, Ringoes, NJ (US); Andrew M. Chon, Princeton, NJ (US)

(21) Appl. No.: 16/040,154

(22) Filed: Jul. 19, 2018

(51) Int. Cl. H01M 10/48; G01R 31/36; H02J 7/00

(52) U.S. Cl. CPC H01M 10/48; H02J 7/0021; H02J 7/0016; G01R 31/3658

(57) ABSTRACT

A battery sensing system acquires battery information of a battery string comprised of multiple battery cells connected in series. The system includes a plurality of battery sensing channels and a digital core including a control unit. Each of the battery sensing channels is configured to acquire inter-terminal voltages of a set of battery cells which are connected in series, so as to comprise at least a portion of a battery string. In some scenarios, the battery sensing system is a system-on-a-chip, disposed in a single integrated circuit package.

### BACKGROUND

### Statement of the Technical Field

The technical field of this disclosure concerns battery systems, and more particularly sensors used in battery systems.

### Description of the Related Art

Large-scale lithium-ion battery systems for making hybrid/electric vehicle (xEV) or large-capacity energy storage system (ESS) consist of a plurality of battery cells which are assembled together to form battery modules or battery packs. A large-scale battery system can comprise many of these battery modules or battery packs. Proper electric and thermal management of a large-scale battery system is imperative. During the operations of a battery system, voltage, current, or temperature differences among the battery cells can lead to electrical imbalances from cell to cell. These imbalances can reduce the performance and life-time of the pack. Therefore, sensing devices are required that are capable of measuring voltage of individual cells connected in series in each pack. In addition, parallel-connected battery cells require current sensing devices to prevent damage and to identify defective cells.

### SUMMARY

This document concerns a battery sensing system. The system is configured to acquire battery information of a battery string comprised of multiple battery cells connected in series. The system is comprised of several parts which include a plurality of battery sensing channels and a digital core including a control unit. Each of the battery sensing channels is configured to acquire inter-terminal voltages of a set of battery cells which are connected in series, so as to comprise at least a portion of a battery string. In some scenarios, the battery sensing system is a system-on-a-chip, disposed in a single integrated circuit package.

In the battery sensing system, each sensing channel includes a voltage sensing front end circuit which is configured to selectively provide as an output a plurality of analog voltage measurements. The voltage sensing front end of each sensing channel is comprised of a plurality of switches which are configured to selectively electrically connect to the voltage sensing front end predetermined battery terminals of selected ones of the plurality of battery cells in the set for measuring inter-terminal battery cell voltages. The analog voltage measurements output by the voltage sensing front end corresponds to a voltage output of an individual one of the plurality of battery cells in the set. Each sensing channel further includes main and redundant analog-to-digital converters (ADCs). Each main and redundant ADC is configured to receive the plurality of analog voltage measurements and generate a plurality of digital voltage measurements.

In the battery sensing solution described herein, each of the plurality of sensing channels is configured to read an inter-terminal voltage twice for each of the plurality of battery cells in the set. This is accomplished by successively using the main and the redundant ADC to independently produce two consecutive digital voltage measurements for each battery cell. The digital core unit is configured to verify the reliability of an inter-terminal voltage measurement for each battery cell by comparing the two consecutive digital voltage measurements.

Each of the sensing channels further include a channel power management unit (CPMU). The CPMU is configured to regulate a power supply voltage applied to each of the voltage sensing front circuit, and the main and redundant ADCs. An input voltage of the CPMU is obtained from a battery terminal of a top battery cell of the set, and having a voltage output that is a sum of the battery cell voltages in the set. The CPMU is configured to generate three reference-point DC voltages, and each sensing channel is configured to selectively apply each of the three reference-point DC voltages to an analog input of both the main and redundant ADC. According to one aspect, the control unit is configured to identify a fault condition in the main ADC if the main ADC response to any of the three reference point voltages is determined to be outside of a predetermined acceptable range. The control unit can be further configured to reassign the redundant ADC as the main ADC if a fault condition is identified in the main ADC. In order to ensure that the fault does not lie in the reference voltage generator, the three reference-point DC voltages are redundantly generated by a first and a second reference voltage generator.

The digital core is comprised of a control unit (e.g. a microprocessor or microcontroller) which is configured to monitor the plurality of digital voltage measurements from each of the sensing channels. Capacitive isolation is provided at a signaling interface to facilitate digital data transmission between the digital core and each of the plurality of sensing channels. The capacitive isolation signaling interface is comprised of a plurality of capacitors which provide galvanic isolation between the digital core and each of the plurality of sensing channels. The digital core determines based on such monitoring the occurrence of a sensing system fault in an identified faulty one of the plurality of sensing channels. The identified faulty one of the plurality of sensing channels can be associated with a first set of the plurality of battery cells. According to one aspect, the control unit in such a scenario is configured to automatically cause a substitute one of the plurality of sensing channels to be configured to sense the first set of the plurality of battery cells in place of the identified faulty one of the plurality of sensing channels.

The battery sensing system also includes a sensor power management unit (S-PMU). The S-PMU is configured to manage a power-up sequence of the battery sensing system, and provide regulated power supply voltages to the digital core. According to one aspect, the S-PMU has as an input power source a top voltage (VTOP) of the battery string.

The battery sensing system can also include a string-level sensing channel. The string-level sensing channel is advantageously configured to selectively acquire a plurality of analog sensor measurements from sensor signals associated with the battery string. These measurements can include for example a temperature of the plurality of battery cells and a cell current of the battery string. The string level-sensing channel is comprised of analog circuitry for acquiring the plurality of analog sensor measurements and a multiplexer. The multiplexer selectively communicates the analog sensor measurements to a one of the plurality of sensing channels. These analog sensor measurements are converted to a digital format in the main and redundant ADCs of the first one of the sensing channels.

In the solution disclosed herein each sensing channel advantageously includes a Sum-of-Channel-Cell (SOCC) sensing input which can be selectively coupled to the main and redundant ADCs to facilitate a direct measurement of a sum of the voltages which are produced by the battery cells which are series connected in the set. The sensing channel is configured to communicate an SOCC digital measurement value to the control system, and the control system is configured to compare the SOCC digital measurement value to a computed sum of individual battery cell voltages for the set based on the plurality of digital voltage measurements. Consequently, the control system can identify a fault in at least one lead connecting a battery cell to the sensing channel if the SOCC digital measurement is different from the computed sum by a predetermined amount.

### BRIEF DESCRIPTION OF THE DRAWINGS

This disclosure is facilitated by reference to the following drawing figures, in which like numerals represent like items throughout the figures, and in which:

FIG. 1 is a block diagram of a conceptual configuration of battery sensors in a large-scale battery system;

FIGS. 2A-2B are commonly used battery sensing architectures;

FIG. 3 is a drawing that is useful for understanding a basic architecture of a fault tolerant battery sensing (FTBS) system;

FIG. 4 is a block diagram that is useful for understanding an analog sensing frontend (ASF) used for certain auxiliary sensing inputs.

FIG. 5A is a drawing that is useful for understanding a power management architecture in the FTBS system of FIG. 3;

FIG. 5B is a drawing that is useful for understanding a current flow through the FTBS system of FIG. 3;

FIG. 6 is a block diagram that is useful for understanding an example architecture for a sensing channel in the FTBS of FIG. 3;

FIG. 7 is a block diagram that is useful for understanding how a redundant sensing channel can be used in case of a fault condition in one sensing channel; and

FIG. 8 is a detailed block diagram which is useful for understanding how a redundant sensing channel can be used to alleviate a fault condition in a sensing channel.

### DETAILED DESCRIPTION

It will be readily understood that the solution described herein and illustrated in the appended figures could involve a wide variety of different configurations. Thus, the following more detailed description, as represented in the figures, is not intended to limit the scope of the present disclosure, but is merely representative of certain implementations in various different scenarios. While the various aspects are presented in the drawings, the drawings are not necessarily drawn to scale unless specifically indicated.

Two known international industrial safety standards include: (1) IEC 61508—entitled “Functional Safety of Electrical/Electronic/Programmable Electronic Safety-related Systems”, and (2) ISO 26262, entitled “Road vehicles—Functional safety”. IEC 61508 is published by the International Electrotechnical Commission (IEC) and is set forth as a basic functional safety standard to ensure the safety of any type of electronic or electrical system. ISO 26262 is an adaptation of IEC 61508 for Automotive Electric/Electronic Systems as set forth by the International Organization for Standardization (ISO). As such, ISO 26262 is intended for ensuring the functional safety of electrical and/or electronic systems in production automobiles.

Functional safety is defined in ISO 26262 as freedom from unacceptable risks, due to hazards caused by malfunctions of an electric/electronic system. Pursuant to the guidelines set forth in ISO 26262, it is mandatory that a component or a system is transferred to a safe state should a failure occur. Several additional criteria emphasized in ISO 26262 are that (1) a system must guard against any single point failure creating a hazard, (2) hazards must be detectable even in the event the primary monitor fails, (3) it is preferable that any redundant circuit is of a less complex design than the primary (4) the redundant components should be independent, and (5) the extent of diagnostic coverage of the components should match the hazard level.

A battery management system (BMS) fundamentally constitutes a safety component of a large scale battery system. Properly handling such a complex battery system during its entire life cycle can be effectively achieved by utilizing the proper quality and safety management apparatus. In a solution presented herein, the broad safety goals outlined in IEC 61508 and ISO 26262 are effectively and economically achieved in a BMS by utilizing a novel battery sensor and system architecture.

The solution disclosed herein involves a fault-tolerant stacked multi-cell battery sensor in the form of a system-on-chip (SoC). The solution is particularly applicable to large-scale battery systems. More specifically, the present disclosure relates to a high-accuracy multi-cell battery sensor with a sensing system architecture that ensures a high degree of fault-tolerance. The highly reliable fault-tolerant sensing system features multi-cell sensing channels, including redundant sensing channels. Each sensing channel contains independent dual-channel analog-to-digital converters (including a main analog-to-digital converter (ADC) and a redundant ADC) as well as two different or separate reference voltage generators for the two ADCs. The built-in fault diagnosis process can monitor the battery sensor for faults, continuously, periodically or occasionally. If faults occur, it is designed to identify the cause of the fault and execute appropriate operations or countermeasure to respond accordingly. Various aspects of the system are described below in greater detail.

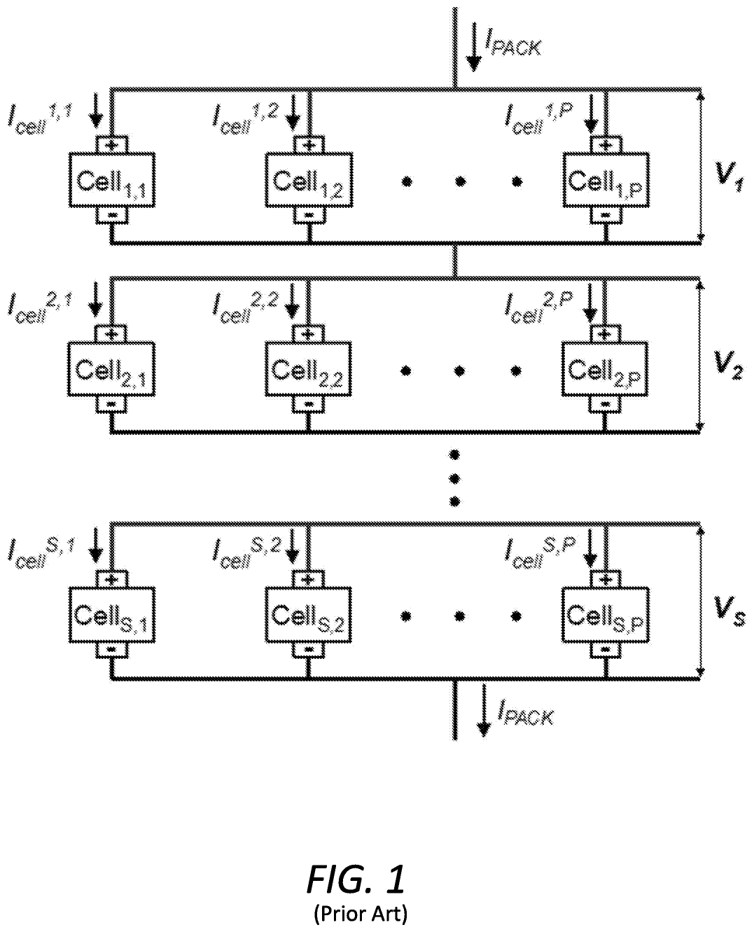

A general configuration of a large-scale battery system is shown in FIG. 1. The number of necessary cells and the configuration of the cell connection in a particular implementation are selected to meet output voltage and power capacity requirements for a particular battery pack or module. The number of cells connected in series determines the output voltage of the battery system. The number of cells connected in parallel determines the amount of current flow and power capacity of the battery system. Cells are usually connected in parallel first and then connected in series, as shown in FIG. 1. As a battery pack is arranged to include P cells in a row and S cells in a column, it follows that the pack will contain (P*S) cells. The cells in a row (Cell_{s,p}|_{p=1 . . . P}) have a same voltage of Vₛ, while the sum of cell voltages in a column is equal to a pack voltage; Σₛ₌₁^{S}Vₛ=V_{PACK}. The cells in a row (Cell_{s,p}|_{p=1 . . . P}) may have different cell current of I_{CELL}^{s,p}, and the sum of cell currents in a row is equal to the pack current; Σₚ₌₁^{P}I_{CELL}^{p}=I_{PACK}.

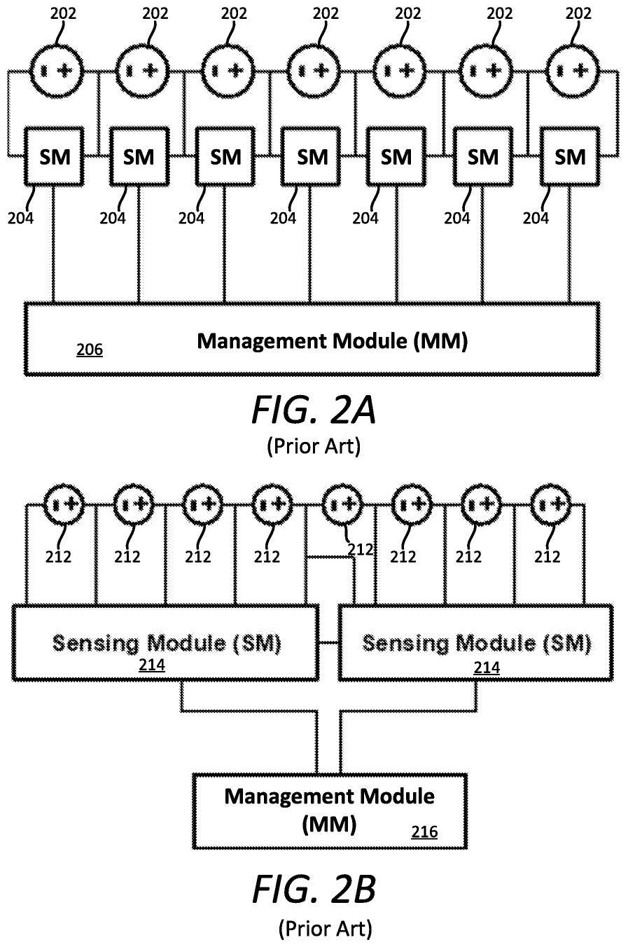

There are several different battery management system (BMS) topologies to optimally obtain useful data of each battery, such as voltage, current, temperature, pressure or impedance, in a large-capacity battery pack. FIG. 2A illustrates a distribution-type single-cell sensing topology, in which a plurality of sensing modules (SMs) 204 are provided respectively to directly measure the voltage across each cell 202. The information from the SMs is then communicated to a management module (MM) 206 While this scheme may not be concerned with voltage isolation between series-connected batteries, it may have the disadvantages of data isolation, high component count and complex connection lines. Accordingly, the topology in FIG. 2A can give rise to cost and scalability issues. In contrast, there is shown in FIG. 2B a modular-type multi-cell sensing topology. The modular-type topology has been commonly used in the large-scale battery applications because it can provide a relatively simple, compact and cost-effective solution. In this topology, sensing modules 214 measure the voltages of various taps in series-connected battery cells 212, and calculate each cell voltage as the voltage difference between two taps. The information from the plurality of sensing modules is then communicated to the management module 216.

Regardless of which topology is chosen for cell sensing, the key issue is how to build the best battery monitoring and management system. A BMS fundamentally constitutes a safety component. Properly handling such a complex battery system during its entire life cycle can only be effectively achieved by employing the related standards and the existence of the proper quality and safety-management apparatus. For this reason, the solution disclosed is oriented toward facilitating compliance with IEC 61508 and ISO 26262.

According to one aspect, a sensing solution is disclosed herein which introduces a degree of redundancy with regard to sensing functionality. This redundant sensing can reduce the probability that one electronic failure will leave the battery and charging system in a state that allows, or even engenders, a significantly destructive cell mishap. Further, the battery system monitoring solution disclosed herein can facilitate the continuation of full safe operation after any single unrepaired sensing system fault. In fact, the system can facilitate such operations even and after most unrepaired secondary and tertiary faults. These and other advantages are achieved in a sensing system with dual redundant battery monitoring and management functional circuitry arranged in independent, fault isolated modules.

A conventional dual redundant BMS configuration arrangement is comprised of independent, fault isolated modules. For example, a conventional redundant BMS may consist of two identical battery monitoring integrated circuits (ICs). In some scenarios, one of these ICs can serve as a primary monitor and the second IC can serve as a back-up battery monitoring IC. In such scenarios, the primary and back-up battery monitor ICs complement each other to collect the necessary information to manage the system, and to provide an additional independent safety mechanism. These systems can work well but will necessarily involve increased expense because two separate monitoring ICs are necessary to maintain independent fault isolated modules.

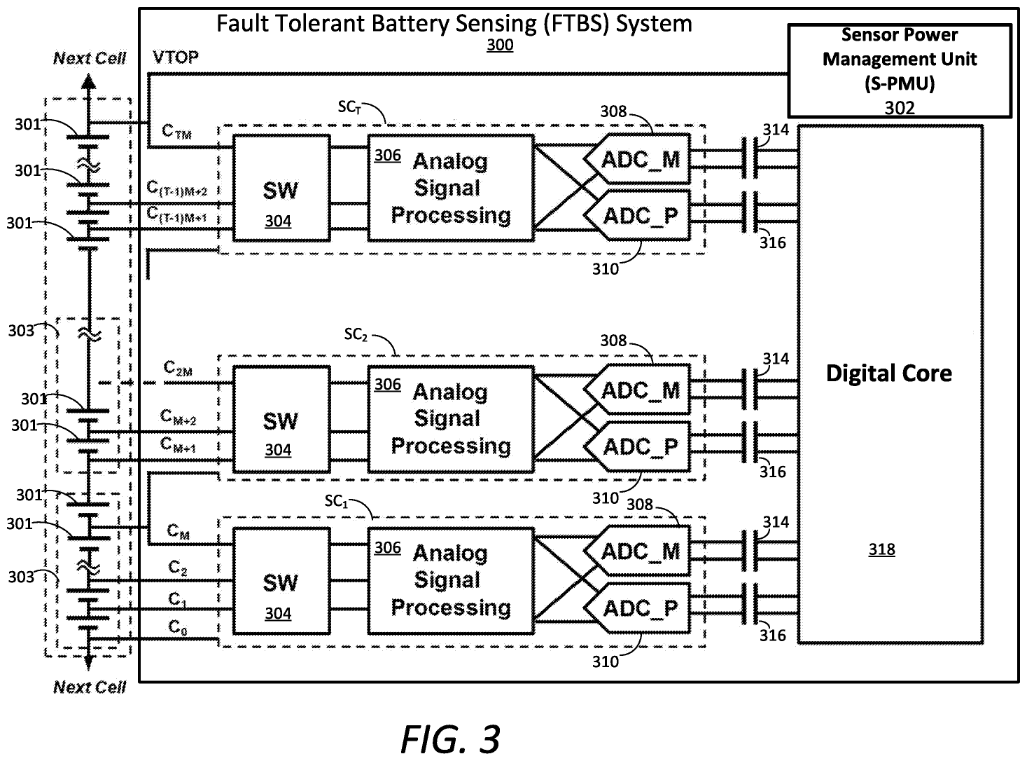

Accordingly, a solution disclosed herein provides a single-chip fault tolerant multi-cell battery sensor system. The system is advantageously comprised of a single integrated circuit so that the solution is essentially a battery sensing system-on-a-chip (SOC). However, in some scenarios the solution can be comprised of a single package multi-chip-module (MCM). Referring now to FIG. 3, there is shown a high level block diagram of a fault tolerant battery sensing (FTBS) system 300, which includes a plurality of redundant cell monitoring components and a built-in multiple-step sensing validation test. More particularly, the FTBS system 300 is comprised of an N-cell battery sensor (where N is an integer value greater than 1). The N-cell battery sensor is comprised of a plurality of identical sensing channels SC₁, SC₂ . . . SC_{T}. Each sensing channel is responsible for voltage measurements of M battery cells 301 (where M is an integer value greater than 1). As such, each sensing channel includes a switching array 304, analog signal processing (ASP) circuitry 306, a main ADC 308 and a redundant ADC 310. The FTBS system further includes an isolated power management unit 302 with dual reference voltage generators, dual analog-to-digital converters, and a ‘Sum of M-cell in a sensing channel’ measurement circuitry (not shown in FIG. 3).

One or more of the sensing channels SC₁ SC₂ . . . SC_{T} is/are designated as backup or auxiliary sensing channels. These backup or auxiliary sensing channels are provided so that they can, if necessary, can take on the role of a sensing channel that develops a fault and therefore does not operate properly. Accordingly, a backup or auxiliary sensing channel can be understood to be one of the sensing channels SC₁, SC₂ . . . SC_{T} that is in excess of those that are needed by the FTBS system to perform battery sensing of the N cells. A digital core 318 controls the measurement operations. The digital core 318 receives sensing data from a main ADC 308 and a redundant ADC 310 of each sensing channel. This sensing data is communicated to the digital core 318 through capacitive couplings 314, 316 and confirms the validation of sensory data. The capacitive couplings provide galvanic isolation between each sensing channel and the digital core unit. The galvanic isolation involves using differential high voltage capacitors that capacitive couple digital-type AC signals from the digital core to the sensing channel, or vice versa while effectively sustaining high common-mode voltages.

Failure mode and effect analysis (FMEA) methodology in compliance with ISO 26262 standard has proven itself useful in the prevention and mitigation of potential failure modes of battery sensors in battery management systems. An FMEA analysis of the battery sensor in such systems involves identifying the failure and then evaluating the effects and causes. Within this context, an FMEA of a battery sensor shows that the failure of the battery sensor to operate or the occurrence of incorrect data sensing can severely affect the functional stability of the EVs or battery pack systems.

For example, the potential failure mode of “no sensory data measured” is a condition in which the battery management system is unable to determine the status of a particular battery cell. The potential causes or mechanisms of such failure are numerous and can include an interface communication failure between the sensing modules and a control module, an open connection between the battery cell and the sensing modules, damage to the sensor module caused by electro-static discharge (ESD) or manufacturing, failure of a power-up sequence, failure to generate a clock signal for the ADC, an electrical short circuit on the printed circuit board (PCB), and so on.

Another type of potential failure involves situations where incorrect sensory data is measured. This type of failure can lead to false calculation of the status of charge (SoC) or misinterpreted diagnostic results. Cell voltage measurement is straightforward, and its accuracy directly relies on the resolution of analog-to-digital converter (ADC). Therefore, the potential causes of inaccurate measurement usually involve problems with relating to the ADC such as reference voltage drift, time-varying offset or residue error, malfunction of ADC logic, and/or noise interference with the battery input lead or power/ground network. These and other direct or indirect factors or failure mechanisms can create unsafe conditions on large-scale battery packs. In order to prevent such unsafe conditions, the solution disclosed herein involves a fault-tolerant battery sensor application specific integrated circuit (ASIC) based on a two-step protection approach for effective fault detection and fault prevention.

Referring once again to FIG. 3, it can be observed each sensing channel is made up of M cell sensors for an M-cell channel battery string 303. The ratio of N to M can be an integer number (N/M=T=1, 2, 3 or more), but not necessarily. For example, in a scenario in which a battery sensor is provided for sensing a 16-cell battery string, one sensing channel can handle 16 cells, 8 cells, 4 cells, 2 cells or 1 cell. The N/M ratio (T) can be determined depending on required measurement synchronization, measurement reliability, occupied silicon area, and so on. Sensing channels use a rank value to identify respective sensing channels. For example, in one scenario a sensing channel 1 (SC₁) can be provided with a rank “1”, sensing channel 2 (SC₀) can be provided with a rank “2”, and so on. It is noted that a lesser rank value indicates lower cells in the series. So, as an example, in FIG. 3 SC₁ processes the measurement of the M cells 301 that correspond to the lowest side battery terminal.

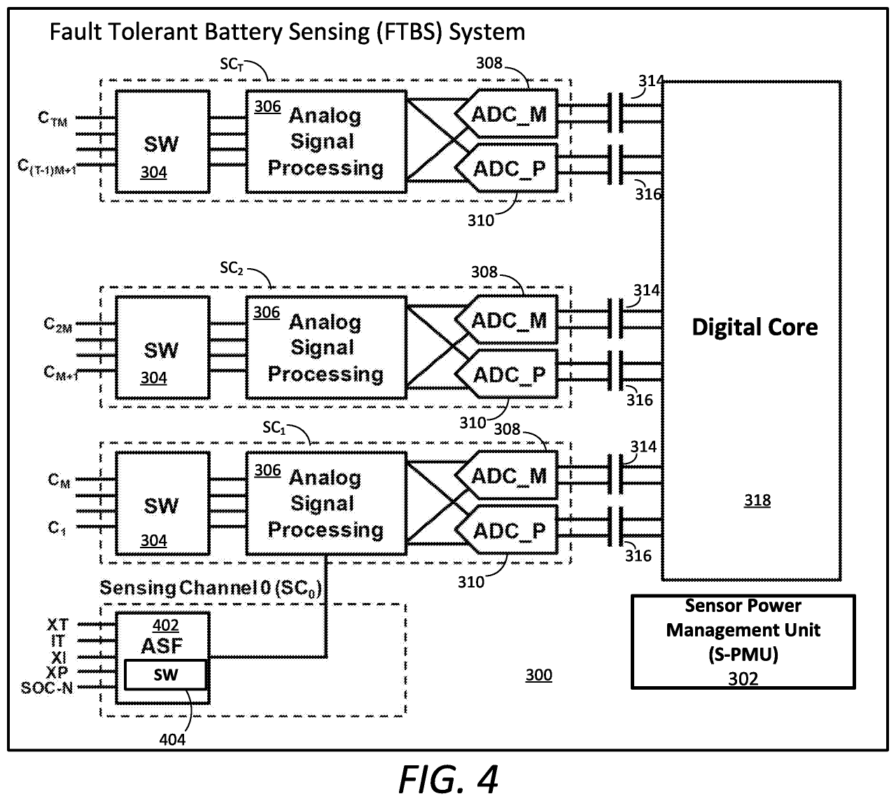

As shown in FIG. 4, a separate sensing channel SC₀ is provided with an analog sensing frontend (ASF) 402. The ASF 402 includes a plurality of input ports and analog front-end circuitry to facilitate processing of inputs from a plurality of sensing elements (not shown). These sensing elements can include input ports for one or more of a cell temperature sensor(s) (XT), an on-chip die temperature sensor (IT), a shunt-resistive current sensor (XI), a cell pressure sensor (XP), and Sum-of-N-cell SOC-N voltage sensor. This sensing channel is designated as having a rank “0” (SC₀). By means of a switching matrix (SW) 404 and appropriate switch selection, the sensing channel SC₀ can be reconfigured to voltage-type outputs. Stated differently, the input of the sensing channel SC₀ can be temperature or current, but the output of the SC₀ will advantageously be converted to voltage so that is suitable for evaluation by ADCs 308, 310. The signals from SC₀ are processed by the same ADCs 308, 310 in sensing channel SC₁ to minimize the size and required power.

The measured cell voltage, temperature or current information in each sensing channel is transferred to the digital core 318 in binary code form through the ADCs 308, 310. Since each sensing channel is connected to a different point along the battery stack, they will each measure a different potential. For example, SC₂ will generate a binary code corresponding to a higher voltage level than SC₁ or the digital core 318. A capacitive isolation signaling technique is used for signaling between each of the sensing channels and the digital core, since each will experience a difference in ground potential. Isolating the electrical grounds in this way advantageously prevents the flow of unwanted electrical current, while ensuring that proper data communications are maintained.

Sensor power management unit (S-PMU) 302 is responsible for various functions. These functions can include coordinating a power-up sequence, controlling regulated power to an embedded digital backend and I/O interface, controlling regulated power to other integrated circuits, controlling sleep and power-down functions, and generating the system clock at a certain frequency for digital backend and sensing channels. The S-PMU 302 can also be configured to continuously execute diagnostics on the various power-related operations and can check them against certain predetermined power-saving settings.

An FTBS system 300 disclosed herein is advantageously powered directly from the stacked battery cells that are to be measured or monitored. As a result, each of the cell terminals are connected to the readout circuits for voltage measurement, but some cell terminals are also used to power the circuit blocks of the FTBS system. If the sensing lines are not well isolated from the power (or, ground) lines, internal fluctuations or noise in the power (or, ground) lines can cause a serious degradation of the sensing accuracy. Moreover, different current draws at the cell terminals can bring charge or voltage imbalance between cells and effect on the cell lifetimes. Accordingly, special consideration is required with respect to the design of robust power and ground networks in the FTBS system 300.

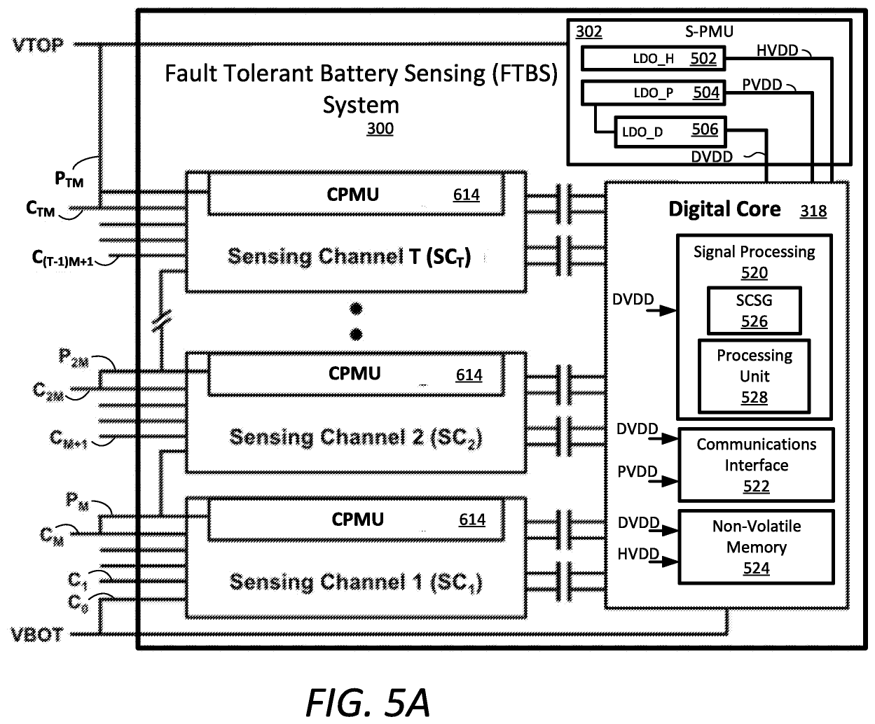

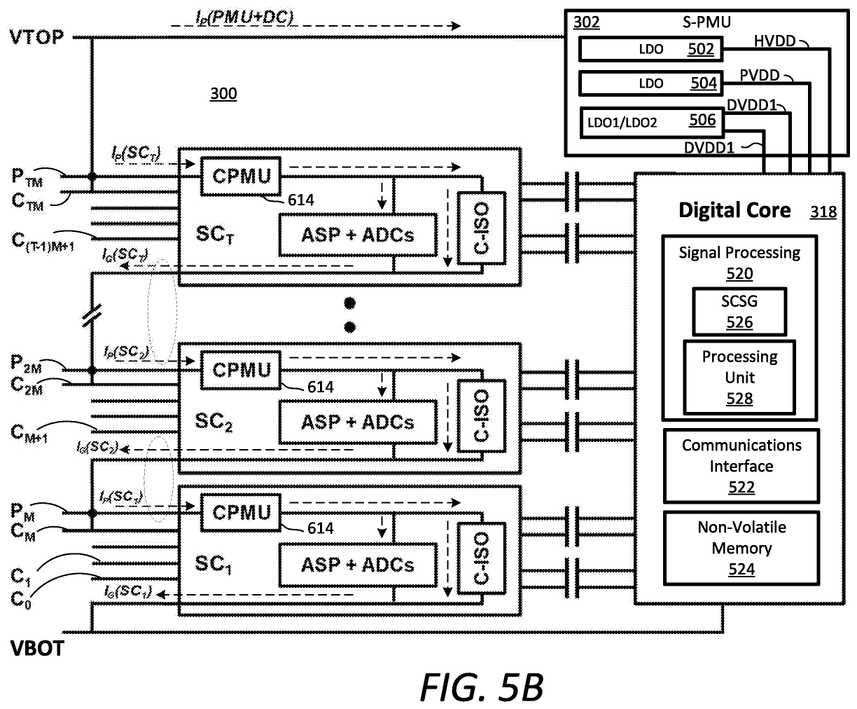

The power network design requires a topology that can stably supply power to the critical circuit blocks while accounting for overall system reliability and noise constraints. Accordingly, an advantageous topology for a power/ground network in the FTBS system 300 is shown in FIGS. 5A and 5B. The topology addresses the various design requirements outlined above and also accounts for variations in the cell current demands.

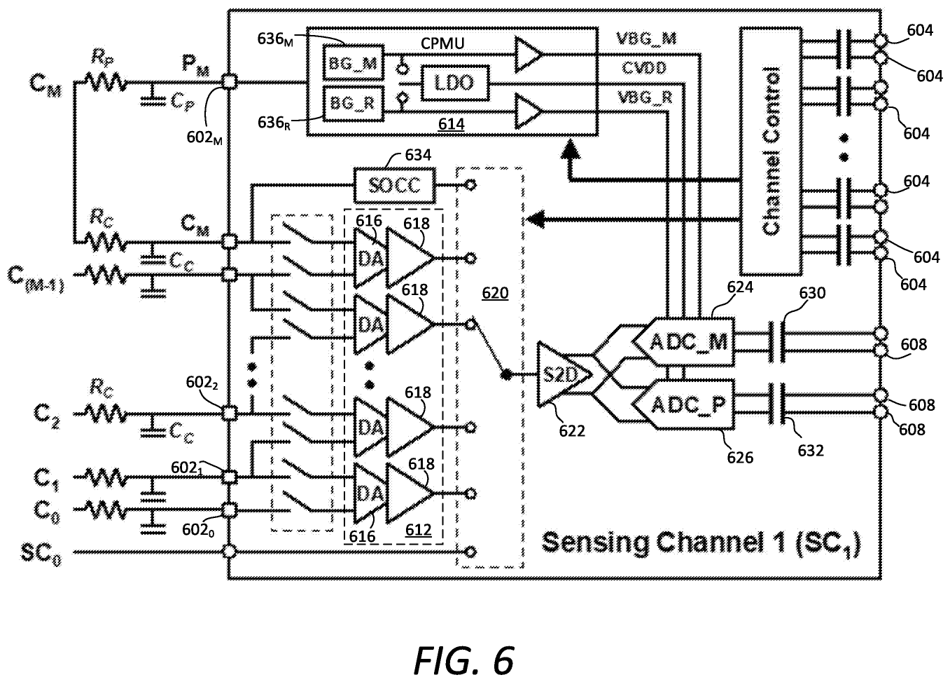

In FIGS. 5A and 5B an FTBS 300 is electrically connected to a battery stack at a bottom end terminal (VBOT) and at a top end terminal (VTOP). It can also be observed that certain cell terminals of the FTBS 300 which are intermediate of VTOP and VBOT function as both a sensing line (e.g., C_{M}, C_{2M}, . . . C_{TM}) and a power (or, ground) line (P_{M}, P_{2M}, . . . P_{TM}). The conductive traces for these cell terminal lines are advantageously separated from each other on a printed circuit board (PCB) in which FTBS 300 is installed and are applied to the FTBS system 300 through individual or separate filter stages. As best understood with reference to FIG. 6, the filter stages can be comprised of a resistor (R_{c}) and capacitor (C_{c}) network, which are collectively referred to herein as an RC network.

Each sensing channel SC₁, . . . SC_{T} has a channel power management unit (CPMU) 614. Details concerning the CPMU 614 are discussed below with reference to FIG. 6. The highest rank cell terminal in a sensing channel is used as a power supply in the sensing channel, as well as used as a ground of the next higher rank sensing channel. In FIG. 5B electric currents for each sensing channel are shown by the arrows. If two sensing channels (e.g., SC₁ and SC₂ in this scenario) are both concurrently performing a sensing operation, the current flowing in the power line (Iₚ(SC₁)) and the ground line (I_{G}(SC₂)) is advantageously canceled. The same amount of current is flowing in each case but the current direction is different. This technique can reuse the charge and advantageously avoids any potential problem with cell unbalancing.

The S-BMU 302 for the FTBS system 300 is advantageously coupled directly to VTOP and can include two or more linear voltage regulators 502, 504, and 506. In some scenarios these devices can be selected to be low-dropout regulators (LDOs). LDOs are well known in the art and can provide an inexpensive way to regulate a lower output voltage powered by a higher voltage source. The regulated output voltages from the liner voltage regulators are used provide the necessary power supply inputs to the digital core 318. FIG. 5A shows an example of regulated power supplies such as HVDD of 5V for the non-volatile memory and PVDD of 3.3V for I/O interface, which are directly regulated from the VTOP. In addition, the DVDD is regulated from the PVDD to generate a 1.8V for the digital core.

Also shown in FIGS. 5A and 5B are certain functional elements associated with the digital core 318. In particular, it can be observed in FIGS. 5A and 5B that digital core 318 is comprised of a signal processing block 520, communication interface 522, and embedded multiple time programmable (MTP) non-volatile memory 524. The embedded sensor signal processor consists of sensor control signal generator (SCSG) 526, and at least one processing unit 528. The processing unit 528 functions as a control unit. As such the processing unit is configured to perform various tasks including sensory data processing, cell diagnosis, calibration coefficient calculations, and power-down sequence control. The SCSG 526 generates various control signals which are necessary for controlling certain operations of the sensor channels as described herein. For example, these operations can include substituting an extra or redundant one of the sensing channel for a particular sensing channel which is determined to have a fault condition. The communication interface 522 can be a Serial Peripheral Interface (SPI), a Controller Area Network (CAN), a Universal Asynchronous Receiver/Transmitter (UART), or an Inter-Integrated Circuit (I2C). The communication interface 522 can facilitate communications with a remote computing system or user interface which is provided to facilitate monitoring of the FTBS 300.

A detailed block diagram of an exemplary sensing channel SC₁ is provided in FIG. 6. Each of the remaining sensing channels SC₂ . . . SC_{T} would have a similar configuration. Accordingly, FIG. 6 is sufficient for understanding the configuration of a sensing channels. As shown in FIG. 6, the sensing channel SC₁ consists of M series-connected battery string input ports 602₀, 602₁, . . . 602_{M}, control signal ports 604, an M-cell voltage, switches 610, measurement sensor array 612, data output ports 608, and a channel power management unit (CPMU) 614 with a dedicated power and ground. The cell input ports 602₀, 602₁, . . . 602_{M} and switches 610 serve to connect the battery cell terminals to the cell voltage sensor 610. Further, a top voltage of a battery string supplied to each sensing channel can be detected by a Sum-of-Channel-Cell (SOCC) sensing input 634. The purpose of the SOCC sensing input 634 will be described below in greater detail.

The M cell battery terminals 602₀ . . . 602_{M} are electrically isolated from the cell voltage measurement sensor by the electrical switches 610. The switches 610 help minimize any leakage current from the battery stack during sleep or power-down mode. The control signal ports 604 receive a plurality of control signals and an internal clock signal (not shown). These signals are received from the digital core 318 through capacitive isolation signaling. The control signals selectively activate any sensing channel operations within the particular sensing channel. For example, the control signals can regulate operations which involve regulated power generation in the sensing channel, a cell voltage sensing sequence, analog-to-digital conversion, and cell balancing operations. Calibration control and mapping data can also be communicated to the sensing channel through the control signal ports 604.

In an M-cell voltage measurement sensor noise-rejection filters are advantageously provided on a circuit board (not shown) in which the FTBS 300 is installed. For example, as shown in FIG. 6, the noise rejection filters can be comprised of a resistor R_{c} and capacitor C_{c} network (RC network) at the input of each of the M cell battery terminals 602₀ . . . 602_{M}.

The M-cell voltage sensor SC₁ measures battery cell voltages by using switches 610 to connect the terminals of each particular battery cell to differential amplifier (DA) 616. The output of the DA 616 is coupled to a buffer amplifier 618. The output of the buffer amplifier 618 is coupled to through a switch 620 to a single-to-differential converter amplifier (S2D) 622. The differential analog output measurement signal is then converted to a digital format in ADC_M 624 and ADC_P 626. The digital measurement output from these units is then communicated to the digital core 318. The issue of signal transmission between the blocks having different ground potential is addressed by using a capacitive isolation signaling technique (e.g. using capacitors 630, 632). Power management in a sensing channel is activated by an SC enable signal from the digital core 318.

In a scenario disclosed herein, the M battery cells comprising a battery stack are connected in series. Accordingly, level shifters are needed to translate the individual cell input common-mode voltage to sensing channel ground for the ADC to process the conversion. The cell common-mode voltage is translated by the difference amplifier (DA) 616. The DA 616 can measure the difference between two the voltage output of two adjacent cell in the battery stack, and its topology can be either in voltage mode or in current mode. In combination with the RC filter network on the circuit board, the DAs 616 serve as low-pass filters to reduce the effect that aliasing can have upon the ADCs. The combination can also help to remove noise on the cell inputs due to various transients in the battery cell voltage. The outputs of the DAs 616 are multiplexed and delivered to the S2D 622 and ADC driver. Note that a sensing channel has two parallel ADCs—a main ADC_M 624 and a redundant ADC_P 626. The two ADC units will each independently measure the same cell voltage so that two measurements are obtained. The ADCs measurements are performed in sequence so that the battery voltage measurements can be more secure. By comparing the data from these two measurement, the reliability of the measurement data can be further enhanced.

In the FTBS system 300, cell voltage measurement is straightforward, and its accuracy directly relies on the resolution of the ADC. For a battery management system, static sensor performance is of primary interest. A static response curve is valid for a range of sensor inputs. In a scenario disclosed herein the sensor input range can be given by [0V, 5V]. Over this range of inputs, the battery sensor output range is defined by [0V, 5V]. In reality, the true situation is more complex and various faults can occur in a battery sensor.

It is possible to identify three factors that undermine the ability to determine and work with the static response curve—drift, noise, and hysteresis. Drift is the change in the static response curve over time. This change may be due to short-term environmental conditions, such as temperature change or humidity, or it may be due to long-term effects, such as aging, wear, fatigue, or oxidation. The most common type of drift is an output drift wherein the response curve shifts by a constant voltage or varying the slope of the static response curve across the input range. The usefulness of the response curve is also undermined by the presence of noise that is superimposed on the measurement. Noise can arise from external disturbances acting on the battery pack systems, or it may be inherent in the battery sensor. In any event, the presence of noise effectively replaces the static response curve by an envelope of static response curves. The static response curve can also adversely affected if the sensor has hysteretic behavior. Hysteresis occurs when the input variable moves away from a given value and then returns to it, with the second measurement different from the first. The repeatability of a sensor is determined by the hysteresis of the static response curve.

There are situations where the failure of a battery sensor causes a potential hazard. The battery sensor must provide protection against those hazards. However, if a battery sensor cannot recognize the occurrence of failures with respect to battery or sensor operations, then the protection is lost. Accordingly, measurement credibility of an FTBS disclosed herein is improved by providing various ways to check the measurement accuracy and to detect the measurement failures or faults.

An important factor in voltage measurement is the accuracy of the ADC. The ADC accuracy can be checked from various key specifications such as integral nonlinearity error, offset and gain errors, and the accuracy of the voltage reference, temperature effects, and AC performance. Inaccuracies in the reference voltage (VREF) can be caused by a number of factors, such as initial accuracy, temperature drift, thermal hysteresis, and long-term stability. The variation in VREF over temperature is defined by its temperature coefficient (TC) or temperature drift. The majority of monolithic references are based on a bandgap reference. A bandgap reference designed for drifts less than 10 ppm/° C. generally requires special circuitry to reduce the second-order temperature coefficient (TC2) effect. This correction is often mentioned as some form of “curvature correction.” The initial accuracy of VREF indicates how close to the stated nominal voltage the reference voltage is guaranteed to be at room temperature under stated bias conditions. A bandgap reference can have relatively loose initial accuracy (5-10%) and will therefore often require some form of calibration. In addition, the ADC characteristics may be further degraded by voltage and thermal imbalance in the signal path. Components along the signal path where these degradations can occur include the digital-to-analog converters (DACs) and/or amplifiers. Degradations can also occur due to analog-output signals, duty cycle imbalances, phase noise of the clock, or device failures due to the electric stress.

In an FTBS system 300, extensive built-in self-test (BIST) can be provided to diagnose the measurement accuracy of the sensing channel and enhance the ability to meet functional safety requirements. For example, the BIST can include three-point DC voltage sensing, redundant ADC sensing and sum-of-cell measurements in a sensing channel. These various self-test features are described below in greater detail. The BIST is automatically executed after the power-up sequence is performed to check the condition of the sensor, and if necessary, the BIST operations described herein can be controlled by the processing unit 528.

As shown in FIG. 6, a CPMU 614 in each sensing channel will include a plurality of reference voltage generators. For example, in some scenarios two reference voltage generators can be used. These reference voltage generators will include a main reference voltage generator (BG_M) 636_{M} and a redundant reference voltage generator (BG_R) 636_{R}. Each reference generator will produce three known DC voltages—V_{RM}, V_{RT}, and V_{RB}. More particularly, V_{RM} can be a center voltage at the center of a reference voltage range, V_{RT} can be a top voltage at a top of a reference voltage range, and V_{RB} can be a bottom voltage at a bottom of a reference voltage range. These voltages can be sequentially injected into the input of each ADC just after the battery sensor is powered up. More particularly, the three reference voltages are sequentially connected to the input of the ADC to perform the ADC calibration—V_{RM} for offset calibration, and then V_{RT} and V_{RB} for gain error calibration. A digital algorithm executed by the processing unit 528 can compare the measured ADC output to the ideal digital output for each DC input voltage. Based on this comparison, the processing unit 528 can estimate measurement errors that can occur in the read path. These measurement errors can include those which are caused by the frontend circuitry of the sensor (e.g. DA 616, buffer amplifier 618, and S2D 622) and the ADC of the particular battery sensor. In addition, the processing unit can note the occurrence of any deviation of the measured values with respect to the main and the redundant ADCs. In both tests, user-configured thresholds of measurement errors are flexibly defined. A large, continuous range of trip-point settings with respect to acceptable errors can be user selected to allow the FTBS 300 to have flexibility to work with any type of Li-ion battery chemistries. When the measured value exceeds the allowable measurement error, the processing unit 528 can generate an accuracy fault signal.

A further aspect of the BIST described herein can involve (1) measuring the top voltage supplied to each sensing channel using a Sum-of-Channel-cell (SOCC) 634 input and (2) measuring the top voltage VTOP supplied to the FTBS 300 using a Sum-of-Sensor-cell (SOSC) sensing. The SOSC sensing can be performed by a dedicated sensor or through the ASF 402. These two measurements can be used to help evaluate the reliability of the individual battery cell voltage measurement. More particularly, the SOCC measurement can be compared to a calculated summation of individual cell voltage measurements for a particular sensing channel. Similarly, the SOSC sensing can be compared to a calculated summation of the individual cell voltage measurements for an entire battery stack connected to the FTBS 300. Such comparison can be one of the best metrics to judge the accuracy of individual battery cell voltage measurement and can also facilitate measurement fault diagnosis.

If a wire connecting a particular battery cell to the sensing board is an open circuit from the connector or the wire is broken (i.e., open-wire or lead-break case), the battery system must recognize this fault and take further actions. In some scenarios, Zener diodes are provided on the sensing board for protecting the input terminal for each cell sensor. In such scenarios, the presence of the Zener diode can further complicate the fault diagnosis. In this case, a calculated sum of the voltages read from each individual cell in the sensing channel will be different from the value of SOCC measurement. Therefore, the SOCC measurement can be an important metric to allow an open-circuit fault as described to be distinguished from a fault involving a scenario in which the battery cell is fully discharged.

For redundancy purposes, main and redundant ADCs are provided in an FTBS 300 described herein. The redundant ADCs complement each other to collect the necessary information to manage the system, and provide an additional independent safety mechanism. The redundant ADC does not need to be a less complex design as compared to the main ADC, and, importantly, the two ADCs are independent with no shared resources. In this regard, the two ADC will advantageously have different reference voltages, which are generated from two different reference voltage generators. The main reference voltage generator BG_M and redundant reference voltage generator BG_R are respectfully identified in FIG. 6 by reference numerals 636_{M} and 636_{R}.

Accordingly, the FTBS system 300 guards against any single point failure creating a hazard. The two ADCs each measure the cell voltage, temperature, or current sensing process at almost the same time and the processing unit 528 reports whether the difference between the two ADC results exceeds a predetermined the threshold value. In the FTBS 300 disclosed herein an additional source of data is provided by a redundant ADC. This additional source of data aids the system in arriving at the correct decision, and as a result, it is used as a method to check the reliability of accuracy. It is also designed to verify measurement accuracy by measuring with a redundant ADC so as to detect when the characteristic of the main ADC is noticeably deteriorated.

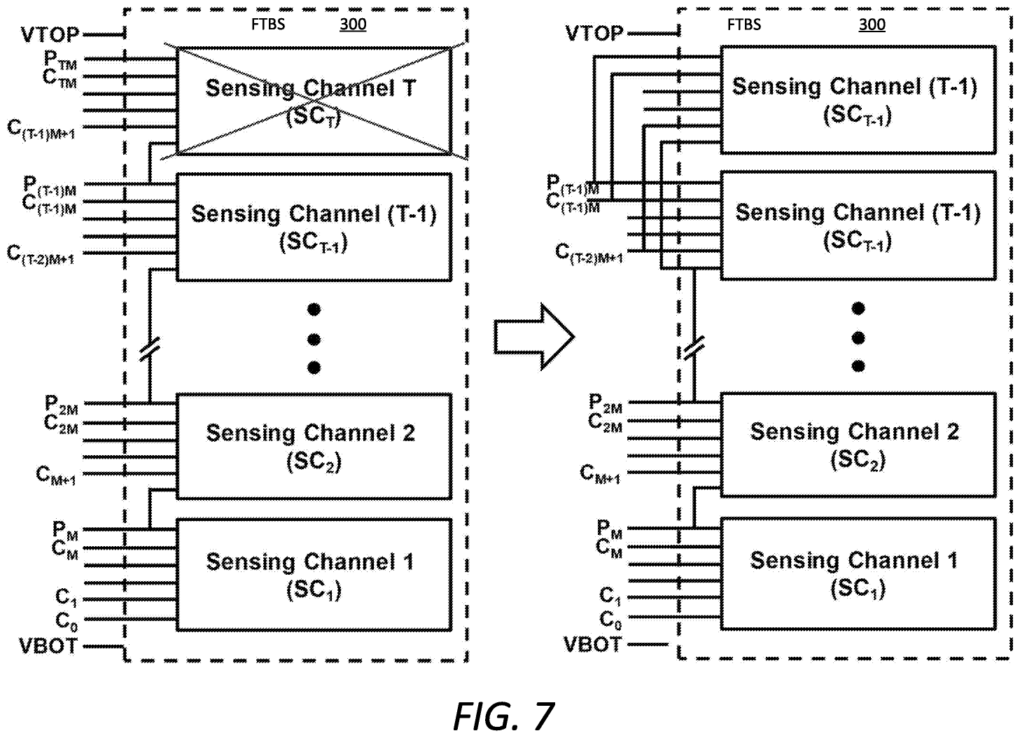

FIG. 7 further illustrates a proposed redundant sensing scheme in a multi-cell battery sensing system-on-a-chip. Redundant sensing channels are provided on an FTBS device (e.g. an ASIC). The redundant sensing channels can be arranged as shown in proximity to a sensing channel where faults may arise. The systems and techniques for built-in fault diagnosis are used to diagnose the occurrence of a failure of a specific sensing channel. When a fault is detected in a particular sensing channel (e.g. sensing channel SC_{T}), that sensing channel will be automatically replaced with a redundant sensing channel (e.g., sensing channel SC_{(T-1)}). Provided that the sensing channel (e.g., SC_{T}) having a higher channel rank is not already in use in a battery module configuration, this sensing channel can be used as a redundant sensing channel of the immediately adjacent lower rank sensing channel (e.g. SC(_{T-1})), as shown in FIG. 7.

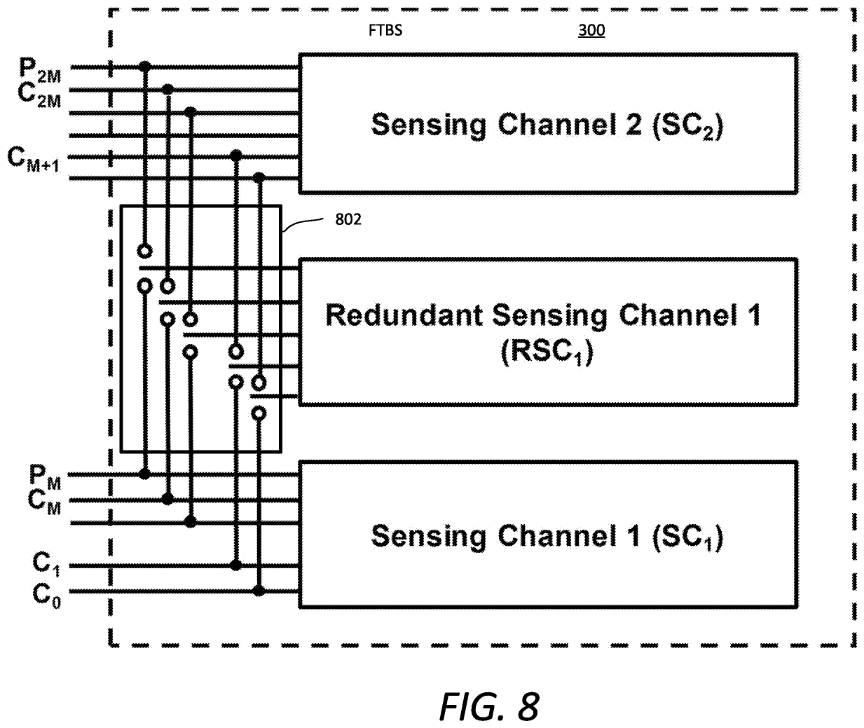

Alternatively, a redundant sensing channel can be pre-positioned between sensing channels. Such a scenario is shown in FIG. 8. As illustrated therein, a redundant sensing channel (in this example, RSC₁) can be selectively reconfigured as an active sensing channel. For example, such reconfiguration can occur in the event of a detected malfunction of an adjacent one of the sensing channels (e.g., SC₁ or SC₂). In some scenarios, the reconfiguration can occur under the control of processing unit 528. When the processing unit 528 detects a faulty sensing channel, it can reconfigure a switching matrix 802 to change the electrical connections between the battery cells and the sensing channels. Accordingly, a string of battery cells which are connected to a sensing channel SC₁ or SC₂ can instead be connected to a redundant sensing channel RSC₁.

Another proposed redundant sensing scheme is a folded sensor architecture. The goal of this architecture is to maximally utilize the available sensing channels to thereby provide a redundant sensing capability. For example, suppose that an FTBS 300 as described herein requires the use of only half of the available sensing channels due to the topology of a battery module. For convenience, this half of the group of available sensing channels can be referred to as the primary sensing channels. In such a scenario, a dual sensing configuration can be facilitated by applying the unused sensing channels (sensing channels other than the primary sensing channels) to completely overlap or duplicate the sensing functions of the primary sensing channels. This half of the group can be defined as redundant sensing channels. In this case, a dual sensing scheme can be achieved simply by connecting the series-connected battery cell terminals (in parallel) to the input ports of the primary sensing channels and to the input ports of the redundant sensing channels.

The described features, advantages and characteristics disclosed herein may be combined in any suitable manner. One skilled in the relevant art will recognize, in light of the description herein, that the disclosed systems and/or methods can be practiced without one or more of the specific features. In other instances, additional features and advantages may be recognized in certain scenarios that may not be present in all instances.

As used in this document, the singular form “a”, “an”, and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to”.

Although the systems and methods have been illustrated and described with respect to one or more implementations, equivalent alterations and modifications will occur to others skilled in the art upon the reading and understanding of this specification and the annexed drawings. In addition, while a particular feature may have been disclosed with respect to only one of several implementations, such feature may be combined with one or more other features of the other implementations as may be desired and advantageous for any given or particular application. Thus, the breadth and scope of the disclosure herein should not be limited by any of the above descriptions. Rather, the scope of the invention should be defined in accordance with the following claims and their equivalents.

We claim:

1. A battery sensing system that acquires battery information of a battery string comprised of multiple battery cells connected in series, comprising:
a plurality of sensing channels, each configured to acquire inter-terminal voltages of a set of the plurality of battery cells which are connected in series comprising at least a portion of the battery string, each sensing channel comprising:
a voltage sensing front end circuit which is configured to selectively provide as an output a plurality of analog voltage measurements, each corresponding to a voltage output of an individual one of the plurality of battery cells in the set;
main and redundant analog-to-digital converters (ADCs), each configured to receive the plurality of analog voltage measurements and generate a plurality of digital voltage measurements;
a channel power management unit (CPMU) configured to regulate a power supply voltage applied to each of the voltage sensing front circuit, and the main and redundant ADCs; and
a digital core including a control unit configured to monitor the plurality of digital voltage measurements from each of the sensing channels, and to determine based on said monitoring the occurrence of a sensing system fault in an identified faulty one of the plurality of sensing channels.

2. The battery sensing system according to claim 1, wherein the faulty one of the plurality of sensing channels is associated with a first set of the plurality of battery cells, and the control unit is configured to automatically cause a substitute one of the plurality of sensing channels to be configured for sensing the first set of the plurality of battery cells in place of the faulty one of the plurality of sensing channels.

3. The battery sensing system according to claim 1, further comprising a string-level sensing channel configured to selectively acquire a plurality of analog sensor measurements from sensor signals associated with the battery string, including a temperature of the plurality of battery cells and a cell current of the battery string.

4. The battery sensing system according to claim 3, wherein the string level-sensing channel is comprised of analog circuitry for acquiring the plurality of analog sensor measurements and a multiplexer to selectively communicate the analog sensor measurements to a first one of the sensing channels.

5. The battery sensing system according to claim 4, wherein the analog sensor measurements are converted to a digital format in the main and redundant ADCs of the first one of the sensing channels.

6. The battery sensing system according to claim 1, further comprising a sensor power management unit (S-PMU) configured to manage a power-up sequence of the battery sensing system, provide regulated power supply voltages to the digital core, the S-PMU configured to have as an input power source a top voltage (VTOP) of the battery string.

7. The battery sensing system according to claim 1, further comprising a capacitive isolation signaling interface facilitating digital data transmission between the digital core and each of the plurality of sensing channels, the capacitive isolation signaling interface comprised of a plurality of capacitors which are configured to provide galvanic isolation between the digital core and each of the plurality of sensing channels.

8. The battery sensing system according to claim 1, wherein the battery sensing system is a system-on-a-chip, disposed in a single integrated circuit package.

9. The battery sensing system according to claim 1, wherein each of the plurality of sensing channels is configured to read an inter-terminal voltage twice for each of the plurality of battery cells in the set by successively using the main and the redundant ADC to independently produce two consecutive digital voltage measurements for each battery cell.

10. The battery sensing system according to claim 9, wherein the digital core unit is configured to verify the reliability of an inter-terminal voltage measurement for each battery cell by comparing the two consecutive digital voltage measurements.

11. The battery sensing system according to claim 1, wherein a voltage sensing front end of each sensing channel is comprised of a plurality of switches which are configured to selectively electrically connect to the voltage sensing front end predetermined battery terminals of selected ones of the plurality of battery cells in the set for measuring inter-terminal battery cell voltages.

12. The battery sensing system according to claim 1, wherein the CPMU is configured to generate three reference-point DC voltages, and each sensing channel is configured to selectively apply each of the three reference-point DC voltages to an analog input of both the main and redundant ADC.

13. The battery sensing system according to claim 12, wherein the control unit is configured to identify a fault condition in the main ADC if the main ADC response to any of the three reference point voltages is determined to be outside of a predetermined acceptable range.

14. The battery sensing system according to claim 13, wherein the control unit is configured to reassign the redundant ADC as the main ADC if a fault condition is identified in the main ADC.

15. The battery sensing system according to claim 12, wherein the three reference-point DC voltages are redundantly generated by a first and a second reference voltage generator.

16. The battery sensing system according to claim 1, wherein an input voltage of the CPMU is obtained from a battery terminal of a top battery cell of the set, and having a voltage output that is a sum of the battery cell voltages in the set.

17. The battery sensing system according to claim 1, wherein each sensing channel has a Sum-of-Channel-Cell (SOCC) sensing input which can be selectively coupled to the main and redundant ADCs to facilitate a direct measurement of a sum of the voltages which are produced by the battery cells which are series connected in the set.

18. The battery sensing system according to claim 17, wherein the sensing channel is configured to communicate an SOCC digital measurement value to the control system, and the control system is configured to compare the SOCC digital measurement value to a computed sum of individual battery cell voltages for the set based on the plurality of digital voltage measurements.

19. The battery sensing system according to claim 18, wherein the control system identifies a fault in at least one lead connecting a battery cell to the sensing channel if the SOCC digital measurement is different from the computed sum by a predetermined amount.
